(19) United States
(12) Patent Application Publication
(10) Pub. No.: US 2026/0305094 A1
(43) Pub. Date: Oct. 1, 2026

(54) Display Motherboard, Display Panel and Display Module

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Wenbiao Ding, Beijing (CN); Yuanjie Xu, Beijing (CN); Meng Li, Beijing (CN); Taofeng Xie, Beijing (CN); Hongjun Zhou, Beijing (CN); Mingzhi Chai, Beijing (CN)

(21) Appl. No.: 19/480,111

(22) PCT Filed: Feb. 10, 2025
(86) PCT No.: PCT/CN2025/076722

§ 371 Date: Oct. 30, 2025

(30) Foreign Application Priority Data
Mar. 26, 2024 (CN) 202410354667.5

(51) Int. Cl. H10K 59/131; H10K 59/12

(52) U.S. Cl. CPC H10K 59/131; H10K 59/1201

(57) ABSTRACT

A display motherboard includes a display region, a frame region located on at least one side of the display region and being provided with bonding terminals arranged in a first direction, and a cutting region located on a side of the frame region away from the display region and being provided with transfer lines arranged in the first direction. An end of a transfer line is correspondingly connected to a bonding terminal, and another end of the transfer line extends in a direction away from the display region. In a second direction, a width of at least one transfer line varies. A maximum width of the transfer line is less than or equal to a width of the bonding terminal.

### CROSS-REFERENCE TO RELATED APPLICATIONS

This application is the United States national phase of International Patent Application No. PCT/CN2025/076722, filed Feb. 10, 2025, and claims priority to Chinese Patent Application No. 202410354667.5, filed Mar. 26, 2024, the disclosures of which are hereby incorporated by reference in their entireties.

### BACKGROUND OF THE INVENTION

### Field of the Invention

The present disclosure relates to the field of display technologies, and in particular, to a display motherboard, a display panel and a display module.

### Description of Related Art

Organic light-emitting diode (OLED) display panels have attracted widespread attention due to their advantages such as self-luminescence, ultra-small thickness, fast response, high contrast, and wide viewing angle.

### SUMMARY OF THE INVENTION

In an aspect, a display motherboard is provided, including: a display region, a frame region located on at least one side of the display region, and a cutting region located on a side of the frame region away from the display region. The frame region is provided with a plurality of bonding terminals arranged in a first direction. The cutting region is provided with a plurality of transfer lines arranged in the first direction. An end of a transfer line is correspondingly connected to a bonding terminal, and another end of the transfer line extends in a direction away from the display region. In a second direction, a width of at least one transfer line varies; a maximum width of the transfer line is less than or equal to a width of the bonding terminal; the second direction and the first direction intersect; the width of the transfer line is a dimension of the transfer line in the first direction; and the width of the bonding terminal is a dimension of the bonding terminal in the first direction.

In some embodiments, the transfer line includes a first transfer segment, a second transfer segment, and a third transfer segment that are connected in sequence; the first transfer segment is connected to the bonding terminal; the third transfer segment extends in the direction away from the display region; and a width of at least a portion of the second transfer segment is less than a width of the first transfer segment, and is less than a width of the third transfer segment.

In some embodiments, in the second direction, a width of the second transfer segment is equal.

In some embodiments, in the second direction, the second transfer segment includes a first segment and a second segment; a first end of the first segment is connected to the first transfer segment, a second end of the first segment is connected to a second end of the second segment, and a first end of the second segment is connected to the third transfer segment; a width of the first segment is decreased in a direction from the first end of the first segment to the second end of the first segment; and a width of the second segment is decreased in a direction from the first end of the second segment to the second end of the second segment.

In some embodiments, a rate of change at which the width of the first segment is decreased in the direction from the first end of the first segment to the second end of the first segment remains constant; and a rate of change at which the width of the second segment is decreased in the direction from the first end of the second segment to the second end of the second segment remains constant.

In some embodiments, in the direction from the first end of the first segment to the second end of the first segment, the first segment includes a plurality of first sub-segments connected in sequence, and a width of a first sub-segment relatively far away from the first transfer segment is less than a width of a first sub-segment relatively close to the first transfer segment; in the direction from the first end of the second segment to the second end of the second segment, the second segment includes a plurality of second sub-segments connected in sequence, and a width of a second sub-segment relatively far away from the third transfer segment is less than a width of a second sub-segment relatively close to the third transfer segment.

In some embodiments, in the second direction, the second transfer segment of the transfer line includes: a plurality of third sub-segments and a plurality of fourth sub-segments that are alternately arranged and connected; a width of each third sub-segment of the plurality of third sub-segments is greater than a width of any fourth sub-segment of the plurality of fourth sub-segments.

In some embodiments, the width of each third sub-segment is equal, and a width of each fourth sub-segment is equal.

In some embodiments, the width of each third sub-segment is equal; in the second direction, the second transfer segment has a middle position; in a direction from the first transfer segment of the transfer line to the middle position, a width of a fourth sub-segment relatively far away from the first transfer segment is less than a width of a fourth sub-segment relatively close to the first transfer segment; in a direction from the third transfer segment of the transfer line to the middle position, a width of a fourth sub-segment relatively far away from the third transfer segment is less than a width of a fourth sub-segment relatively close to the third transfer segment.

In some embodiments, the display motherboard includes: a plurality of conductive layers and a plurality of insulating layers that are alternately arranged; the cutting region includes: a first region, a second region and a third region; the first transfer segment of the transfer line is located in the first region, the second transfer segment of the transfer line is located in the second region, and the third transfer segment of the transfer line is located in the third region; an insulating layer in the first region includes an organic film layer and/or an inorganic film layer; an insulating layer in the second region includes an inorganic film layer; and an insulating layer in the third region includes an organic film layer and/or an inorganic film layer.

In some embodiments, the display motherboard includes: a plurality of conductive layers and an inorganic insulating layer located between every two adjacent conductive layers among the plurality of conductive layers; and at least a pair of two adjacent transfer lines are located in different conductive layers.

In some embodiments, the plurality of transfer lines include: a plurality of first-type transfer lines and a plurality of second-type transfer lines; the plurality of first-type transfer lines and the plurality of second-type transfer lines are located in different conductive layers; in the first direction, the plurality of transfer lines are divided into a plurality of transfer line groups arranged side by side; each transfer line group of the plurality of transfer line groups includes: a first-type transfer line among the plurality of first-type transfer lines and a second-type transfer line among the plurality of second-type transfer lines.

In some embodiments, the plurality of conductive layers include at least one gate metal layer and at least one source-drain metal layer; the first-type transfer lines are located in any one of the at least one gate metal layer, and the second-type transfer lines are located in any one of the at least one source-drain metal layer. Alternatively, the plurality of conductive layers include at least two gate metal layers; the first-type transfer lines are located in any one of the at least two gate metal layers, and the second-type transfer lines are located in a gate metal layer other than a gate metal layer where the first-type transfer lines are located. Alternatively, the plurality of conductive layers include at least two source-drain metal layers; the first-type transfer lines are located in any one of the at least two source-drain metal layers, and the second-type transfer lines are located in a source-drain metal layer other than a source-drain metal layer where the first-type transfer lines are located.

In some embodiments, the plurality of transfer lines further include a plurality of third-type transfer lines; the plurality of third-type transfer lines, the plurality of first-type transfer lines, and the plurality of second-type transfer lines are located in different conductive layers; and the transfer line group further includes: a third-type transfer line among the plurality of third-type transfer lines.

In some embodiments, in a single transfer line group, a third-type transfer line is located on a side of a second-type transfer line away from a first-type transfer line.

In some embodiments, the first transfer segment includes: a portion of a first gate metal layer, a portion of a first source-drain metal layer, and a portion of a second source-drain metal layer that are arranged in sequence; a portion of a first insulating layer is arranged between two adjacent first transfer segments, and the portion of the first insulating layer covers edges of the two adjacent first transfer segments; the second transfer segment includes: a portion of the first gate metal layer; and the first insulating layer is arranged on the first gate metal layer, and the first insulating layer covers the second transfer segment.

In some embodiments, the first transfer segment further includes a portion of a third source-drain metal layer; the third source-drain metal layer and a second insulating layer are arranged on a side of the second source-drain metal layer away from the first source-drain metal layer; and a portion of the second insulating layer is located between two adjacent first transfer segments, and the second insulating layer exposes the third source-drain metal layer.

In some embodiments, the cutting region is further provided with a plurality of unit test terminals, a unit test terminal is correspondingly connected to a transfer line, and the unit test terminals are used to be connected to a test structure for performing a display test on the display motherboard.

In another aspect, a display panel is provided. The display panel includes: a display region, a frame region located on at least one side of the display region, and a cutting sub-region located on a side of the frame region away from the display region. The frame region is provided with a plurality of bonding terminals arranged in a first direction. The cutting sub-region is provided with a plurality of transfer sub-lines arranged in a first direction. An end of a transfer sub-line is correspondingly connected to a bonding terminal, and another end of the transfer sub-line extends in a direction away from the display region. In a second direction, a width of at least one transfer sub-line varies; a maximum width of the transfer sub-line is less than or equal to a width of the bonding terminal; the second direction and the first direction intersect; the width of the transfer sub-line is a dimension of the transfer sub-line in the first direction; and the width of the bonding terminal is a dimension of the bonding terminal in the first direction.

In some embodiments, the transfer sub-line includes a first transfer segment and a second transfer sub-segment; an end of the first transfer segment is connected to the bonding terminal, another end of the first transfer segment is connected to an end of the second transfer sub-segment, and another end of the second transfer sub-segment extends in the direction away from the display region; and a width of at least a portion of the second transfer sub-segment is less than a width of the first transfer segment.

In yet another aspect, a display module is provided. The display module includes the display panel as described in any one of the above embodiments. The display module further includes a flexible printed circuit board, the flexible printed circuit board includes a plurality of leads, and the plurality of leads are correspondingly connected to the plurality of bonding terminals located in the frame region of the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely accompanying drawings of some embodiments of the present disclosure, and a person of ordinary skill in the art can obtain other drawings according to those drawings. In addition, the accompanying drawings to be described below may be regarded as schematic diagrams, and are not limitations on actual sizes of products and actual processes of methods involved in the embodiments of the present disclosure.

FIG. 1 is a diagram showing a structure corresponding to a manufacturing process of a display module, in accordance with some embodiments of the present disclosure;

FIG. 2 is an enlarged view of the region A of the display motherboard in FIG. 1;

FIG. 3 is an enlarged view of the region B of the display motherboard in FIG. 2;

FIG. 4 is an enlarged view of the region C of the display motherboard in FIG. 3;

FIG. 5 is a structural diagram of a display motherboard, in accordance with some embodiments of the present disclosure;

FIG. 6 is an enlarged view of the region D of the display motherboard in FIG. 5;

FIG. 7 is a structural diagram of transfer lines, in accordance with some embodiments of the present disclosure;

FIG. 8 is a structural diagram of transfer lines, in accordance with some other embodiments of the present disclosure;

FIG. 9 is a structural diagram of transfer lines, in accordance with yet some other embodiments of the present disclosure;

FIG. 10 is a structural diagram of transfer lines, in accordance with yet some other embodiments of the present disclosure;

FIG. 11 is a structural diagram of transfer lines, in accordance with yet some other embodiments of the present disclosure;

FIG. 12 is a diagram showing a film layer arrangement structure of a display motherboard, in accordance with some embodiments of the present disclosure;

FIG. 13A is a sectional view of the first transfer segment shown in FIG. 6 taken along the section line EE;

FIG. 13B is another sectional view of the first transfer segment shown in FIG. 6 taken along the section line EE;

FIG. 14 is a sectional view of the connection wire of the display motherboard shown in FIG. 6 taken along the section line GG;

FIG. 15 is a sectional view of the transfer line of the display motherboard shown in FIG. 6 taken along the section line FF;

FIG. 16 is another enlarged view of the region D of the display motherboard in FIG. 5;

FIG. 17 is a sectional view of the transfer line of the display motherboard shown in FIG. 16 taken along the section line HH;

FIG. 18 is yet another enlarged view of the region D of the display motherboard in FIG. 5;

FIG. 19 is a sectional view of the transfer line of the display motherboard shown in FIG. 18 taken along the section line KK;

FIG. 20 is yet another enlarged view of the region D of the display motherboard in FIG. 5;

FIG. 21 is a sectional view of the transfer line of the display motherboard shown in FIG. 20 taken along the section line LL;

FIG. 22 is yet another enlarged view of the region D of the display motherboard in FIG. 5;

FIG. 23 is a sectional view of the transfer line of the display motherboard shown in FIG. 22 taken along the section line MM;

FIG. 24 is yet another enlarged view of the region D of the display motherboard in FIG. 5;

FIG. 25 is a sectional view of the transfer line of the display motherboard shown in FIG. 24 taken along the section line NN;

FIG. 26 is a structural diagram of a display module, in accordance with some embodiments of the present disclosure;

FIG. 27 is an enlarged view of the region Q of the display module in FIG. 26; and

FIG. 28 is another enlarged view of the region Q of the display module in FIG. 26.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of”, “the plurality of” and “multiple” each mean two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection; or it may represent a direct connection, or may represent an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The use of “applicable to” or “configured to” herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values other than those stated.

The term such as “about”, “substantially” or “approximately” as used herein includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

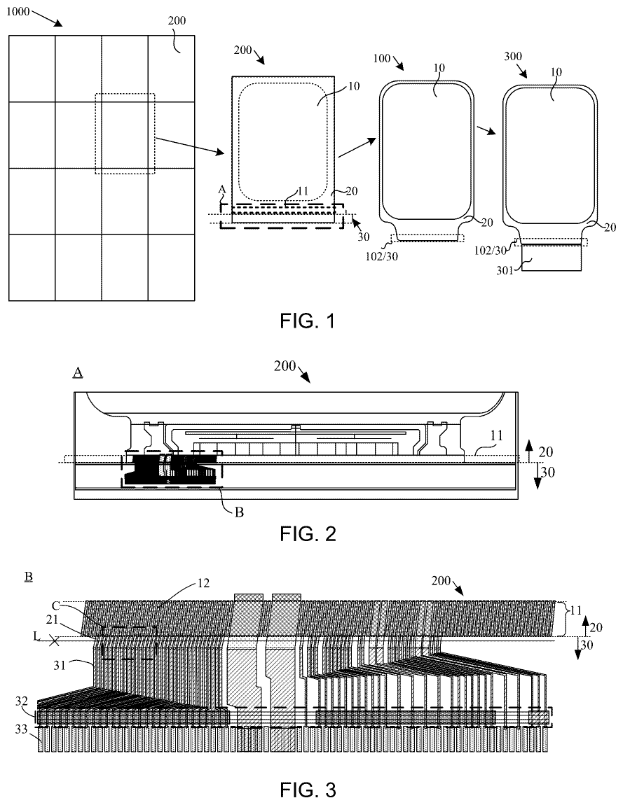

In some embodiments, as shown in FIG. 1, a process of manufacturing a display module 300 may include three process stages: a substrate cutting stage, a panel test stage, and a module stage.

In the substrate cutting stage, a substrate 1000 that has been encapsulated is cut into a plurality of display motherboards 200. Each display motherboard 200 is used to form a display panel 100.

As shown in FIGS. 1 and 2, FIG. 2 is an enlarged view of the region A of the display motherboard 200 shown in FIG. 1. Each display motherboard 200 includes a display region 10, a frame region 20 located on at least one side of the display region 10, and a cutting region 30 located on a side of the frame region 20 away from the display region 10.

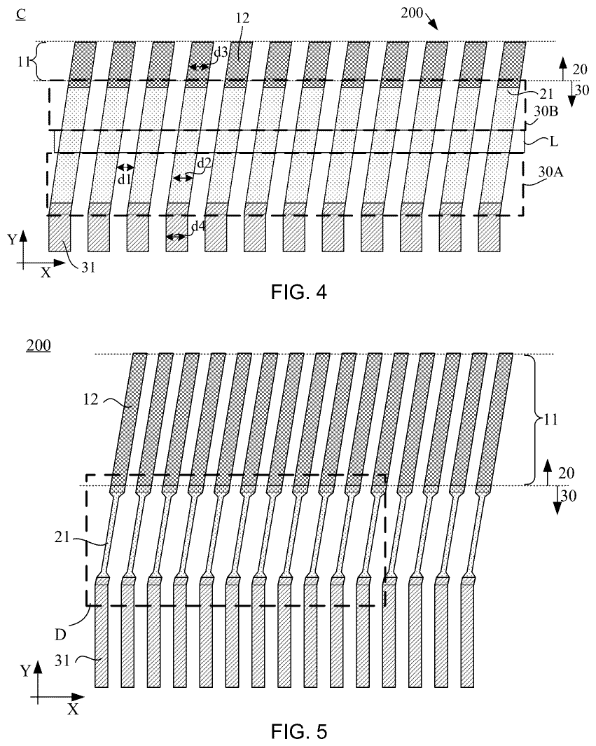

As shown in FIGS. 2 and 3, FIG. 3 is an enlarged view of the region B of the display motherboard 200 shown in FIG. 2. The embodiments of the present disclosure are illustrated by taking an example in which the frame region 20 surrounds the display region 10. The frame region 20 on a lower side of the display region 10 has a bonding region 11. The bonding region 11 is provided with a plurality of bonding terminals 12. The plurality of bonding terminals 12 are correspondingly connected to circuits of the display region 10 and the frame region 20. For example, circuits of the display region 10 include pixel driving circuits and the like, and circuits of the frame region 20 include a gate on array (GOA) circuit and the like. The circuits of the display region 10 and the frame region 20 are used to drive the display region 10 to realize a display function.

The cutting region 30 may be provided with a plurality of transfer lines 21, and ends of the plurality of transfer lines 21 are correspondingly connected to the plurality of bonding terminals 12. For example, the plurality of transfer lines 21 are connected to the plurality of bonding terminals 12 in a one-to-one correspondence. The cutting region 30 is further provided with a plurality of connection wires 31 and a plurality of unit test terminals 33 that are connected. Other ends of the plurality of transfer lines 21 are correspondingly connected to the plurality of connection wires 31. For example, the plurality of transfer lines 21 are connected to the plurality of connection wires 31 in a one-to-one correspondence.

That is, the plurality of transfer lines 21 are used to connect the plurality of unit test terminals 33 to the circuits of the display region 10 and the frame region 20.

For example, in the panel test stage, by inputting direct current (DC) or alternating current (AC) signals to the plurality of unit test terminals 33, the signals are transmitted to the circuits of the display region 10 and the frame region 20 through the plurality of bonding terminals 12 of the bonding region 11 to realize the display of the display region 10, so as to detect the display status of the display region 10. The purpose of the panel test is to detect display defects in the display region 10 and prevent display motherboards 200 with display defects from entering a next process.

For example, the cutting region 30 is further provided therein with an electrostatic discharge unit 32 connected between the plurality of connection wires 31 and the plurality of unit test terminals 33. The electrostatic discharge unit 32 may effectively prevent static electricity from affecting the display of the display region 10.

As shown in FIG. 4, FIG. 4 is an enlarged view of the region C of the display motherboard 200 shown in FIG. 3. In the module stage, a portion of the display motherboard 200 on a side of a cutting path L away from the frame region 20, i.e., a portion 30A of the cutting region 30 located on the side of the cutting path L away from the frame region 20, is removed by cutting along the cutting path L of the cutting region 30 using a laser cutting manner. The display region 10 of the display motherboard 200, the frame region 20, and a portion 30B of the cutting region 30 located on a side of the cutting path L close to the frame region 20 form a display panel 100 (as shown in FIG. 1).

Then, a circuit board is connected to the display panel 100 to form a display module 300. The circuit board is provided with circuits for transmitting various control signals to the display panel 100. For example, the circuits include: a source driver chip (source driver IC), a timing controller (TCON) chip and a power chip. The circuit board includes, for example, a flexible printed circuit board 301. The specific connection between the circuit board and the display panel 100 may be that: a plurality of leads 3011 (as shown in FIG. 27) on the flexible printed circuit board 301 are connected to the bonding terminals 12 (as shown in FIG. 3) of the bonding region 11 of the display panel 100 in a one-to-one correspondence.

However, a distance d1 between adjacent transfer lines 21 is small. Therefore, during the process of laser cutting in the module stage, particles generated by cutting the transfer lines 21, and burns, peeling and cracks in a film layer where the transfer lines 21 are located, etc. may cause a short circuit between adjacent transfer lines 21. Moreover, since a width d2 of the transfer line 21 is relatively high, higher laser energy is required during cutting, and higher laser energy will cause greater thermal damage to the cutting path L, which is more likely to cause a short circuit between adjacent transfer lines 21, affecting the display quality of the display panel 100.

In light of this, as shown in FIGS. 1, 5 and 6, FIG. 6 is an enlarged view of the region D of the display motherboard 200 shown in FIG. 5, the embodiments of the present disclosure provide a display motherboard 200, and the display motherboard 200 includes: a display region 10, a frame region 20 located on at least one side of the display region 10, and a cutting region 30 located on a side of the frame region 20 away from the display region 10. The frame region 20 is provided with a plurality of bonding terminals 12 arranged in a first direction X, and the cutting region 30 is provided with a plurality of transfer lines 21 arranged in the first direction X. An end of the transfer line 21 is correspondingly connected to a bonding terminal 12, and another end of the transfer line 21 extends in a direction away from the display region 10.

For example, the embodiments of the present disclosure are illustrated by taking an example in which the frame region 20 surrounds the display region 10, but the embodiments of the present disclosure are not limited thereto. For example, the frame region 20 may be located on one side of the display region 10.

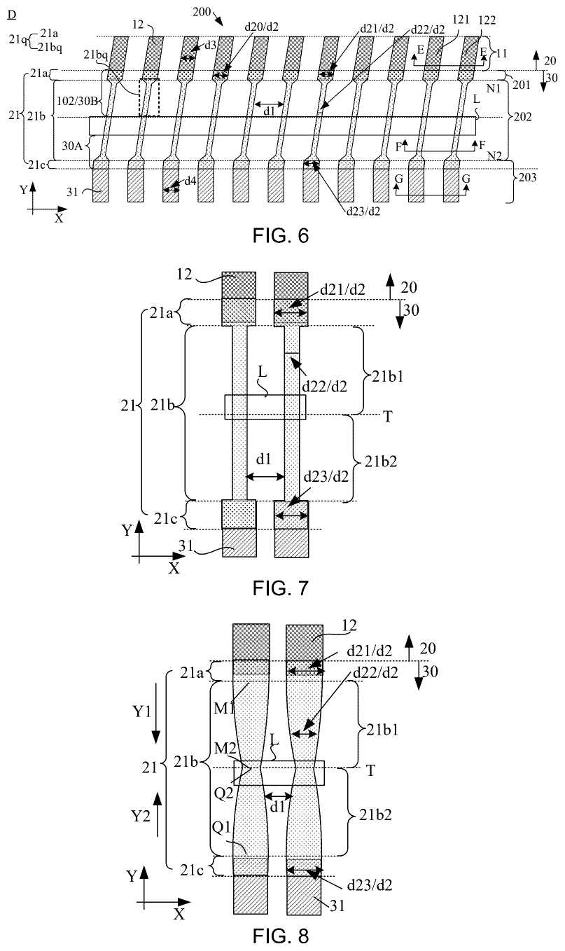

For example, the first direction X is a horizontal direction as shown in FIG. 6, and the frame region 20 and the cutting region 30 are arranged in a vertical direction as shown in FIG. 6. For example, the vertical direction as shown in FIG. 6 is a second direction Y. The plurality of bonding terminals 12 are arranged in the horizontal direction in the frame region 20, the plurality of transfer lines 21 and the plurality of connection wires 31 are arranged in the horizontal direction in the cutting region 30, and a bonding terminal 12, a transfer line 21 and a connection wire 31 are connected in the vertical direction to form a wire for transmitting a DC or AC signal, thereby achieving the purpose of transmitting DC or AC signals to the circuits of the display region 10 and the frame region 20, and facilitating the detection of the display status of the display region 10.

For example, the first direction X is perpendicular to the second direction Y. It will be noted that the vertical direction may be a direction having a certain angle with the second direction Y as shown in FIG. 6; for example, the angle is an acute angle.

For example, as shown in FIG. 3, the cutting region 30 is further provided with a plurality of unit test terminals 33; the unit test terminals 33 are correspondingly connected to the connection wires 31; and the unit test terminals 33 are used to connect a test structure (not shown in the figure) for performing display test on the display motherboard 200.

In some examples, as shown in FIG. 6, in the second direction Y, a width d2 of at least one transfer line 21 varies; and a maximum width d20 of the transfer line 21 is less than or equal to a width d3 of the bonding terminal. The width d2 of the transfer line 21 is a dimension of the transfer line 21 in the first direction X, and the width d3 of the bonding terminal 12 is a dimension of the bonding terminal 12 in the first direction X.

For the transfer line 21 of the display motherboard 200 provided in the embodiments as shown in FIG. 4, the width d2 of the transfer line 21 remains consistent in the second direction Y. Moreover, the width d2 of the transfer line 21 is substantially consistent with the width d3 of the bonding terminal 12, and the width d2 of the transfer line 21 is substantially consistent with a width d4 of the connection wire 31, that is, d2=d3=d4.

As shown in FIG. 6, the width d2 of the transfer line 21 varies in the second direction Y, and the maximum width d20 of the transfer line 21 is less than or equal to the width d3 of the bonding terminal. That is, a width d2 of a portion of the transfer line 21 in the second direction Y is decreased. That is, compared with the transfer line 21 shown in FIG. 4, by decreasing the width d2 of the portion of the transfer line 21, a distance d1 between adjacent transfer lines 21 is increased at the portion where the width d2 of the transfer line 21 is decreased, so that the risk of the short circuit of the transfer lines 21 may be reduced during the process of laser cutting of the module stage.

Moreover, since the width d2 of the portion of the transfer line 21 is decreased, the laser energy required during cutting may be relatively reduced, the degree of thermal damage to the cutting region 30 is mitigated, and the problem of the short circuit between adjacent transfer lines 21 is effectively mitigated.

In some embodiments, as shown in FIG. 6, the transfer line 21 includes a first transfer segment 21a, a second transfer segment 21b, and a third transfer segment 21c that are connected in sequence; the first transfer segment 21a is connected to the bonding terminal 12, and the third transfer segment 21c is connected to the connection wire 31; a width d22 of at least a portion of the second transfer segment 21b is less than a width d21 of the first transfer segment 21a, and is less than a width d23 of the third transfer segment 21c, that is, d22<d21 and d22<d23.

For example, the width d21 of the first transfer segment 21a is substantially consistent with the width d23 of the third transfer segment 21c, the width d21 of the first transfer segment 21a is substantially consistent with the width d3 of the bonding terminal, and the width d23 of the third transfer segment 21c is substantially consistent with the width d4 of the connection wire 31, that is, d21=d23=d3=d4. For example, the width d21 of the first transfer segment 21a and the width d23 of the third transfer segment 21c are both equal to the maximum width d20 of the transfer line 21, that is, d21=d23=d20. Moreover, the width d22 of the second transfer segment 21b is less than the maximum width d20 of the transfer line 21, that is, d22<d20.

That is to say, in the second direction Y, the width d2 of the transfer line 21 is decreased at the second transfer segment 21b. During the process of laser cutting of the transfer line 21 in the module stage, since a position of the cutting path L may be located in a region where the second transfer segment 21b is located, a distance d1 between adjacent second transfer segments 21b is increased by decreasing the width d22 of the second transfer segment 21b. Therefore, it may reduce the risk of the short circuit between adjacent transfer lines 21 caused by particles generated by cutting the transfer lines 21 and burns, peeling and cracks in the film layer where the transfer lines 21 are located.

Moreover, the width d22 of the second transfer segment 21b is less than the width d21 of the first transfer segment 21a, and is less than the width d23 of the third transfer segment 21c, that is, d22<d21 and d22<d23. The laser energy required during cutting may be lower, so that the degree of thermal damage to the cutting region 30 is mitigated, and the problem of the short circuit between adjacent transfer lines 21 is effectively mitigated.

Furthermore, since the width d21 of the first transfer segment 21a is greater than the width d22 of the second transfer segment 21b, it is possible to increase a lapping area of the first transfer segment 21a and the bonding terminal 12 when the first transfer segment 21a is connected to the bonding terminal 12. Since the width d23 of the third transfer segment 21c is greater than the width d22 of the second transfer segment 21b, it is possible to increase a lapping area of the third transfer segment 21c and the connection wire 31 when the third transfer segment 21c is connected to the connection wire 31. Therefore, the transmission stability of DC or AC signals is guaranteed.

In some embodiments, as shown in FIG. 7, in the second direction Y, the width d22 of the second transfer segment 21b is the same.

That is to say, the width d22 of the second transfer segment 21b is less than the width d21 of the first transfer segment 21a, the width d22 of the second transfer segment 21b is less than the width d23 of the third transfer segment 21c, and in the second direction Y, the width d22 of the second transfer segment 21b remains consistent.

Since the distance d1 between adjacent second transfer segments 21b is increased by decreasing the width d22 of the second transfer segment 21b, it may reduce the risk of the short circuit between adjacent transfer lines 21 caused by particles generated by cutting the transfer lines 21 and burns, peeling and cracks in the film layer where the transfer lines 21 are located. The laser energy required during cutting may be lower, so that the degree of thermal damage to the cutting region 30 is mitigated, and the problem of the short circuit between adjacent transfer lines 21 is effectively mitigated.

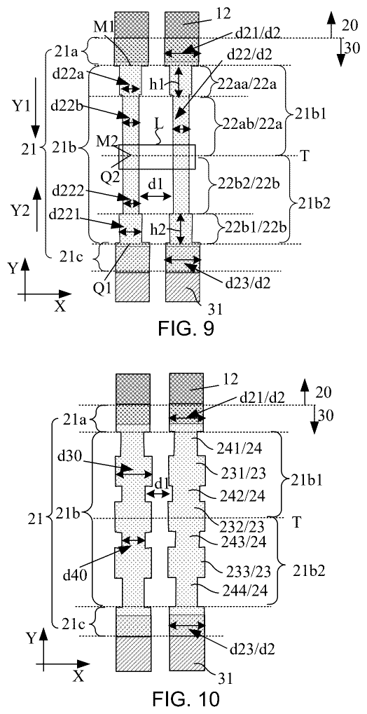

In some embodiments, as shown in FIGS. 8 and 9, in the second direction Y, the second transfer segment 21b includes: a first segment 21b1 and a second segment 21b2. A first end M1 of the first segment 21b1 is connected to the first transfer segment 21a, a second end M2 of the first segment 21b1 is connected to a second end Q2 of the second segment 21b2, and a first end Q1 of the second segment 21b2 is connected to the third transfer segment 21c. A width d22 of the first segment 21b1 is decreased in a direction Y1 from the first end M1 of the first segment 21b1 to the second end M2 of the first segment 21b1. A width d22 of the second segment 21b2 is decreased in a direction Y2 from the first end Q1 of the second segment 21b2 to the second end Q2 of the second segment 21b2.

That is, as shown in FIGS. 8 and 9, in the direction Y1 from the first end M1 of the first segment 21b1 to the second end M2 of the first segment 21b1, the width d22 of the second transfer segment 21b varies. In the direction Y2 from the first end Q1 of the second segment 21b2 to the second end Q2 of the second segment 21b2, the width d22 of the second transfer segment 21b varies.

In some examples, as shown in FIG. 8, a rate of change at which the width d22 of the first segment 21b1 is decreased in the direction Y1 from the first end M1 of the first segment 21b1 to the second end M2 of the first segment 21b1 remains unchanged; and a rate of change at which the width d22 of the second segment 21b2 is decreased in the direction Y2 from the first end Q1 of the second segment 21b2 to the second end Q2 of the second segment 21b2 remains unchanged. That is, in the direction Y1, the width d22 of the first segment 21b1 is decreased uniformly at a certain rate of change. In the direction Y2, the width d22 of the second segment 21b2 is decreased uniformly at a certain rate of change.

For example, the rate of change at which the width d22 of the first segment 21b1 is decreased may be equal to the rate of change at which the width d22 of the second segment 21b2 is decreased. A connection point T between the second end M2 of the first segment 21b1 and the second end Q2 of the second segment 21b2 may be a position where the width d22 of the second transfer segment 21b is minimum. In a case where the cutting path L is located in a region where the connection point T between the second end M2 of the first segment 21b1 and the second end Q2 of the second segment 21b2 is located, lower laser energy may be used to mitigate the degree of thermal damage to the cutting region 30 and effectively mitigate the problem of the short circuit between adjacent transfer lines 21.

In some examples, as shown in FIG. 9, in the direction Y1 from the first end M1 of the first segment 21b1 to the second end M2 of the first segment 21b1, the first segment 21b1 includes a plurality of first sub-segments 22a connected in sequence, and a width d22 of a first sub-segment 22a relatively far away from the first transfer segment 21 a is less than a width d22 of a first sub-segment 22a relatively close to the first transfer segment 21a. In the direction Y2 from the first end Q1 of the second segment 21b2 to the second end Q2 of the second segment 21b2, the second segment 21b2 includes a plurality of second sub-segments 22b connected in sequence, and a width d22 of a second sub-segment 22b relatively far away from the third transfer segment 21 c is less than a width d22 of a second sub-segment 22b relatively close to the third transfer segment 21c.

For example, as shown in FIG. 9, in the direction Y1 from the first end M1 of the first segment 21b1 to the second end M2 of the first segment 21b1, the first segment 21b1 includes two first sub-segments 22a that are connected, which are respectively a first sub-segment 22aa and a first sub-segment 22ab, and the first sub-segment 22aa is closer to the first transfer segment 21a than the first sub-segment 22ab. A width d22b of the first sub-segment 22ab relatively far away from the first transfer segment 21a is less than a width d22a of the first sub-segment 22aa relatively close to the first transfer segment 21a, that is, d22b <d22a.

In the direction Y2 from the first end Q1 of the second segment 21b2 to the second end Q2 of the second segment 21b2, the second segment 21b2 includes two second sub-segments 22b that are connected, which are respectively a second sub-segment 22b1 and a second sub-segment 22b2. The second sub-segment 22b1 is closer to the third transfer segment 21c than the second sub-segment 22b2. A width d222 of the second sub-segment 22b2 relatively far away from the third transfer segment 21c is less than a width d221 of the second sub-segment 22b1 relatively close to the third transfer segment 21c, that is, d222<d221.

For example, the width d22b of the first sub-segment 22ab is equal to the width d222 of the second sub-segment 22b2 connected to the first sub-segment 22ab, that is, d22b=d222. The width d22 a of the first sub-segment 22aa is equal to the width d221 of the second sub-segment 22b1, that is, d22a=d221. Furthermore, a length h1 of the first sub-segment 22aa in the second direction Y is equal to a length h2 of the second sub-segment 22b1 in the second direction Y, that is, h1=h2.

In the second direction Y, the width d22 of the second transfer segment 21b varies, so that the distance d1 between adjacent second transfer segments 21b is increased. Therefore, it may reduce the risk of the short circuit between adjacent transfer lines 21 caused by particles generated by cutting the transfer lines 21 and burns, peeling and cracks in the film layer where the transfer lines 21 are located. The laser energy required during cutting may be lower, so that the degree of thermal damage to the cutting region 30 is mitigated, and the problem of the short circuit between adjacent transfer lines 21 is effectively mitigated.

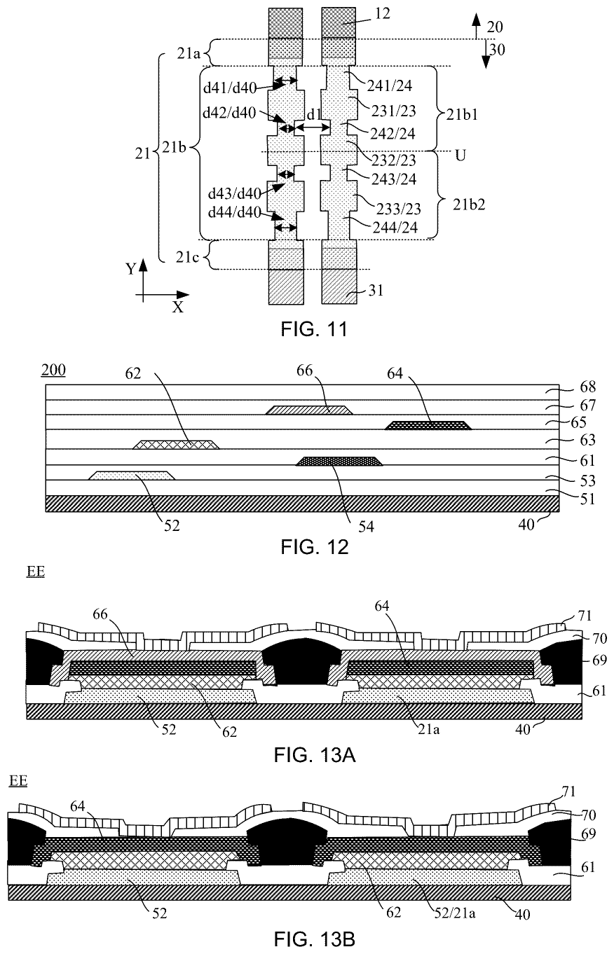

In some embodiments, as shown in FIGS. 10 and 11, in the second direction Y, the second transfer segment 21b of the transfer line 21 includes: a plurality of third sub-segments 23 and a plurality of fourth sub-segments 24 that are alternately arranged and connected. A width d30 of each third sub-segment 23 of the plurality of third sub-segments 23 is greater than a width d40 of any fourth sub-segment 24 of the plurality of fourth sub-segments 24.

The plurality of third sub-segments 23 and the plurality of fourth sub-segments 24 that are alternately arranged means that: a fourth sub-segment 24 is arranged between every two third sub-segments 23; and a third sub-segment 23 is arranged between every two fourth sub-segments 24.

In some examples, as shown in FIG. 10, the second transfer segment 21b includes: a third sub-segment 231, a third sub-segment 232, a third sub-segment 233, a fourth sub-segment 241, a fourth sub-segment 242, a fourth sub-segment 243, and a fourth sub-segment 244. The fourth sub-segment 241, the third sub-segment 231, the fourth sub-segment 242, the third sub-segment 232, the fourth sub-segment 243, the third sub-segment 233 and the fourth sub-segment 244 are connected in sequence to form the second transfer segment 21b.

A width d30 of each third sub-segment 23 is greater than a width d40 of any fourth sub-segment 24, that is, d30>d40. For example, the width d30 of the third sub-segment 23 may be equal to the width d21 of the first transfer segment 21a, and the width d30 of the third sub-segment 23 may be equal to the width d23 of the third transfer segment 21c, that is, d30=d21=d23>d40.

The second transfer segment 21b includes a plurality of fourth sub-segments 24, widths d40 of the fourth sub-segments 24 are decreased, and a distance d1 between adjacent fourth sub-segments 24 is increased. Therefore, it may reduce the risk of the short circuit between adjacent transfer lines 21 caused by particles generated by cutting the transfer lines 21 and burns, peeling and cracks in the film layer where the transfer lines 21 are located. The laser energy required during cutting may be lower, so that the degree of thermal damage to the cutting region 30 is mitigated, and the problem of the short circuit between adjacent transfer lines 21 is effectively mitigated.

In some embodiments, as shown in FIG. 10, the width W30 of each third sub-segment 23 is equal, and the width d40 of each fourth sub-segment is equal.

For example, the second transfer segment 21b includes three third sub-segments 23, which are respectively the third sub-segment 231, the third sub-segment 232 and the third sub-segment 233, and widths d30 of the third sub-segment 231, the third sub-segment 232 and the third sub-segment 233 are the same. The second transfer segment 21b includes four fourth sub-segments, which are respectively the fourth sub-segment 241, the fourth sub-segment 242, the fourth sub-segment 243 and the fourth sub-segment 244, and widths d40 of the fourth sub-segment 241, the fourth sub-segment 242, the fourth sub-segment 243 and the fourth sub-segment 244 are the same.

In some embodiments, as shown in FIG. 11, the width d30 of each third sub-segment 23 is equal. In the second direction Y, the second transfer segment 21b has a middle position U. In a direction from the first transfer segment 21a of the transfer line 21 to the middle position U, a width d40 of a fourth sub-segment 24 relatively far away from the first transfer segment 21a is less than a width d40 of a fourth sub-segment 24 relatively close to the first transfer segment 21a. In a direction from the third transfer segment 21c of the transfer line 21 to the middle position U, a width d40 of a fourth sub-segment 24 relatively far away from the third transfer segment 21c is less than a width d40 of the fourth sub-segment 24 relatively close to the third transfer segment 21c.

It will be noted that the middle position U can be understood as that, in the second direction Y, dimensions from the middle position U to two ends of the second transfer segment 21b are equal.

It can be understood that, the direction from the first transfer segment 21a of the transfer line 21 to the middle position U is the same as the direction Y1 from the first end M1 of the first segment 21b1 to the second end M2 of the first segment 21b1 of the second transfer segment 21b. The direction from the third transfer segment 21c of the transfer line 21 to the middle position U is the same as the direction Y2 from the first end Q1 of the second segment 21b2 to the second end Q2 of the second segment 21b2 of the second transfer segment 21b.

For example, in the direction from the first transfer segment 21a of the transfer line 21 to the middle position U, the fourth sub-segment 242 is farther away from the first transfer segment 21a than the fourth sub-segment 241, and the width d41 of the fourth sub-segment 242 is less than the width d42 of the fourth sub-segment 242, that is, d42<d41. In the direction from the third transfer segment 21c of the transfer line 21 to the middle position U, the fourth sub-segment 243 is farther away from the third transfer segment 21c than the fourth sub-segment 244, and the width d43 of the fourth sub-segment 243 is less than the width d44 of the fourth sub-segment 244, that is, d43<d44.

For example, the width d42 of the fourth sub-segment 242 and the width d43 of the fourth sub-segment 243 may be equal, that is, d42=d43. The width d41 of the fourth sub-segment 242 and the width d44 of the fourth sub-segment 244 may be equal, that is, d41=d44.

Since the widths of the plurality of fourth sub-segments 24 are different, that is, the widths d40 of some fourth sub-segments 24 are further decreased relative to the widths d40 of some fourth sub-segments 24, the distance d1 between the fourth sub-segments 24 whose widths d40 are further decreased is increased. Therefore, it may reduce the risk of the short circuit between adjacent transfer lines 21 caused by particles generated by cutting the transfer lines 21 and burns, peeling and cracks in the film layer where the transfer lines 21 are located. The laser energy required during cutting may be lower, so that the degree of thermal damage to the cutting region 30 is mitigated, and the problem of the short circuit between adjacent transfer lines 21 is effectively mitigated.

In some embodiments, as shown in FIG. 6, the display motherboard 200 includes an organic film layer. Since the organic film layer has poor adhesion performance, the organic film layer is easily separated from adjacent film layer(s). When cutting along the cutting path L using a laser cutting manner, in order to prevent the organic film layer on the cutting path L from being peeled off during the process of laser cutting, there is no organic film layer provided in a part of the cutting region 30.

In order to facilitate understanding of a structural diagram of the film layer arrangement of the cutting region 30, a structural diagram of the film layer arrangement of the display motherboard 200 is introduced below.

For example, as shown in FIG. 12, the display motherboard 200 includes: a base 40, a first gate insulating layer 51, a first gate metal layer 52, a second gate insulating layer 53, a second gate metal layer 54, a first insulating layer 61, a first source-drain metal layer 62, a first passivation layer 63, a second source-drain metal layer 64, a second passivation layer 65, a third source-drain metal layer 66, a planarization layer 67, a pixel definition layer 68, a first inorganic insulating layer 70, and a touch metal layer 71, which are stacked. The first gate metal layer 52, the second gate metal layer 54, the first source-drain metal layer 62, the second source-drain metal layer 64, the third source-drain metal layer 66, and the touch metal layer 71 are conductive layers. The first gate insulating layer 51, the second gate insulating layer 53, the first insulating layer 61, the first passivation layer 63, the second passivation layer 65, the planarization layer 67, the pixel definition layer 68, and the first inorganic insulating layer 70 are insulating layers.

It can be understood that the above film layer structure is only used as an example for introduction herein. In some other embodiments of the present disclosure, the display motherboard 200 may include more or fewer film layers. For example, it includes fewer or more gate metal layers; for example, it further includes a third gate metal layer. For example, it includes fewer or more source-drain metal layers, such as a four source-drain metal layer. For another example, it includes fewer or more passivation layers. For yet another example, it includes fewer or more planarization layers.

For example, materials of the first gate insulating layer 51, the second gate insulating layer 53, the first insulating layer 61, the first passivation layer 63, and the second passivation layer 65 include inorganic materials, for example, the inorganic materials include silicon nitride (SiNx), silicon oxide (SiOx) and silicon nitride oxide (SiNxOy). That is, the first gate insulating layer 51, the second gate insulating layer 53, the first insulating layer 61, the first passivation layer 63 and the second passivation layer 65 are inorganic film layers. The arrangement of the inorganic film layers in the embodiments of the present disclosure is not limited thereto.

For example, materials of the planarization layer 67 and the pixel definition layer 68 include organic materials. For example, the organic materials include polyimide. That is, the planarization layer 67 and the pixel definition layer 68 are organic film layers. The arrangement of the organic film layers in the embodiments of the present disclosure is not limited thereto.

For example, as shown in FIGS. 13A and 13B, FIG. 13A is a sectional view of the first transfer segment 21a shown in FIG. 6 taken along the section line EE, and FIG. 13B is another sectional view of the first transfer segment 21a shown in FIG. 6 taken along the section line EE. The first transfer segment 21a includes: a portion of the first gate metal layer 52, a portion of the first source-drain metal layer 62 and a portion of the second source-drain metal layer 64 that are arranged in sequence. A portion of the first insulating layer 61 is arranged between two adjacent first transfer segments 21a, and the portion of the first insulating layer 61 covers edges of the two adjacent first transfer segments 21a.

As shown in FIG. 15, the second transfer segment 21b includes: a portion of the first gate metal layer 52; and a first insulating layer 61 is arranged on the first gate metal layer 52, and the first insulating layer 61 covers the second transfer segment 21b.

As shown in FIG. 13A, the first transfer segment 21a further includes a portion of a third source-drain metal layer 66; and the third source-drain metal layer 66 and a second insulating layer 69 are arranged on a side of the second source-drain metal layer 64 away from the first source-drain metal layer 62. A portion of the second insulating layer 69 is located between two adjacent first transfer segments 21a, and the second insulating layer 69 exposes the third source-drain metal layer 66.

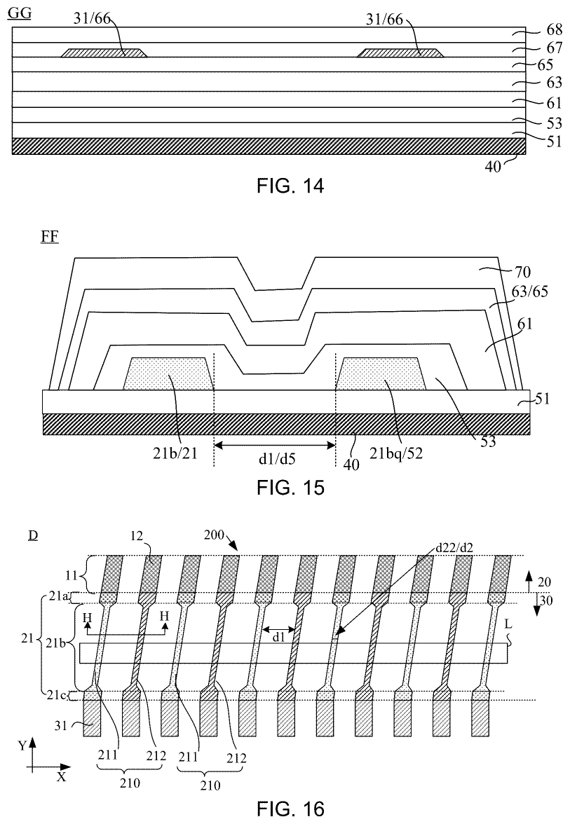

For example, as shown in FIG. 14, FIG. 14 is a sectional view of the connection wire 31 of the display motherboard 200 shown in FIG. 6 taken along the section line GG. The connection wire 31 is located in the third source-drain metal layer 66, and some embodiments of the present disclosure are not limited thereto. The connection wire 31 may also be located in at least one of the first gate metal layer 52, the second gate metal layer 54, the first source-drain metal layer 62, and the second source-drain metal layer 64. The cutting region 30 where the connection wires 31 are located includes organic film layers such as the planarization layer 67 and the pixel definition layer 68.

For example, as shown in FIG. 15, FIG. 15 is a sectional view of the transfer line 21 (the second transfer segment 21b) of the display motherboard 200 shown in FIG. 6 taken along the section line FF. The transfer line 21 is located in the first gate metal layer 52, and some embodiments of the present disclosure are not limited thereto. The cutting region 30 where the second transfer segments 21b are located does not include organic film layers such as the planarization layer 67 and the pixel definition layer 68.

That is, as shown in FIG. 6, in the cutting region 30, the organic film layer(s) have a border N1 and a border N2, and no organic film layer is provided in a region between the border N1 and the border N2.

For example, as shown in FIG. 6, the cutting region 30 includes a first region 201 located on a side of the border N1 close to the bonding region 11. The first region 201 is provided with organic film layer(s), and the first transfer segments 21a are located in the first region 201. The cutting region 30 further includes a second region 202 located between the border N1 and the border N2. A material of film layer(s) of the second region 202 does not include an organic material. That is, the second region 202 is not provided with an organic film layer. The second transfer segments 21b are located in the second region 202. The cutting region 30 further includes a third region 203 located on a side of the border N2 away from the bonding region 11. The third region 203 is provided with organic film layer(s), and the third transfer segments 21c are located in the third region 203.

That is, insulating layer(s) of the first region 201 include an organic film layer and an inorganic film layer; insulating layer(s) of the third region 203 include an organic film layer and an inorganic film layer; and insulating layer(s) of the second region 202 includes an inorganic film layer. That is, the insulating layer(s) of the second region 202 do not include an organic film layer.

Since the film layer(s) of the second region 202 do not include an organic film layer, it may effectively prevent peeling of the film layer(s) during cutting.

In some examples, as shown in FIG. 6, the width d2 of the transfer line 21 may be decreased starting from the border of the organic film layer. That is, in the second direction Y pointing from the bonding region 11 to the cutting region 30, the width d2 of the transfer line 21 is decreased starting from the border N1 of the organic film layer. In the second direction Y pointing from the cutting region 30 to the bonding region 11, the width d2 of the transfer line 21 is decreased starting from the border N2 of the organic film layer.

For example, the cutting path L may be located the region between the border N1 and the border N2 where no organic film layer is provided. Since a width d2 of a portion of the transfer line 21 between the border N1 and the border N2 is decreased, a region where the width d2 of the transfer line 21 is decreased overlaps with a region where the cutting path L is located, which may effectively ensure that the width d2 of the transfer line 21 in the region where the cutting path L is located is relatively small, and the distance d1 between adjacent transfer lines 21 is relatively large, which reduces the risk of the short circuit of the transfer lines 21.

In some embodiments, as shown in FIGS. 12, 16 and 17, FIG. 17 is a sectional view of the transfer line 21 (the second transfer segment 21b) of the display motherboard 200 shown in FIG. 16 taken along the section line HH. The display motherboard 200 includes a plurality of conductive layers and an inorganic insulating layer located between every two adjacent conductive layers among the plurality of conductive layers. Every two adjacent transfer lines 21 are located in different conductive layers.

It should be noted that FIGS. 6, 16, 18, 20, 22 and 24 are respectively enlarged views of the regions D of the display motherboards 200 of six structures.

In some examples, the plurality of conductive layers include: at least one gate metal layer and at least one source-drain metal layer. First-type transfer lines 211 are located in any one of the at least one gate metal layer, and second-type transfer lines 212 are located in any one of the at least one source-drain metal layer.

For example, as shown in FIG. 12, the conductive layers include two gate metal layers and three source-drain metal layers. The two gate metal layers are the first gate metal layer 52 and the second gate metal layer 54. The three source-drain metal layers are the first source-drain metal layer 62, the second source-drain metal layer 64, and the third source-drain metal layer 66. The inorganic insulating layers include: the first gate insulating layer 51, the second gate insulating layer 53, the first insulating layer 61, the first passivation layer 63, and the second passivation layer 65.

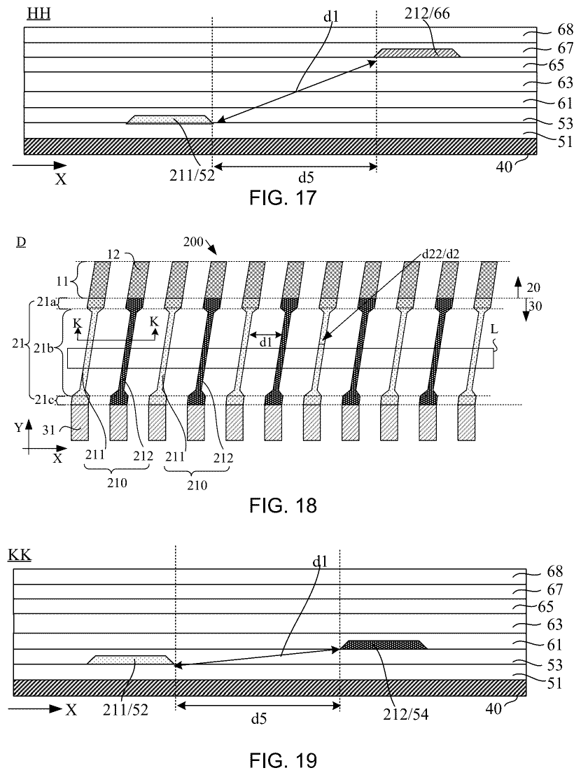

In some examples, as shown in FIGS. 16 and 17, the plurality of transfer lines 21 include: a plurality of first-type transfer lines 211 and a plurality of second-type transfer lines 212. The plurality of first-type transfer lines 211 and the plurality of second-type transfer lines 212 are located in different conductive layers. In the first direction X, the plurality of transfer lines 21 are divided into a plurality of transfer line groups 210 arranged side by side, and each transfer line group 210 of the plurality of transfer line groups 210 includes: one first-type transfer line 211 among the plurality of first-type transfer lines 211 and one second-type transfer line 212 among the plurality of second-type transfer lines 212.

For example, as shown in FIGS. 16 and 17, the first-type transfer lines 211 are located in the first gate metal layer 52, and the second-type transfer lines 212 are located in the third source-drain metal layer 66. The first-type transfer lines 211 and the second-type transfer lines 212 are alternately arranged. That is, a second-type transfer line 212 is arranged between every two adjacent first-type transfer lines 211, and a first-type transfer line 211 is arranged between every two adjacent second-type transfer lines 212. A first-type transfer line 211 and a second-type transfer line 212 that are adjacent to each other constitute a transfer line group 210, and the plurality of transfer line groups 210 are evenly arranged in the first direction X.

In some examples, as shown in FIGS. 18 and 19, FIG. 19 is a sectional view of the transfer line 21 (the second transfer segment 21b) of the display motherboard 200 shown in FIG. 18 taken along the section line KK. The plurality of conductive layers include at least two gate metal layers. The first-type transfer lines 211 are located in any one of the at least two gate metal layers, and the second-type transfer lines 212 are located in a gate metal layer other than the gate metal layer where the first-type transfer lines 211 are located.

For example, the plurality of conductive layers include two gate metal layers, and the two gate metal layers are respectively the first gate metal layer 52 and the second gate metal layer 54. The first-type transfer lines 211 are located in the first gate metal layer 52, and the second-type transfer lines 212 are located in the second gate metal layer 54.

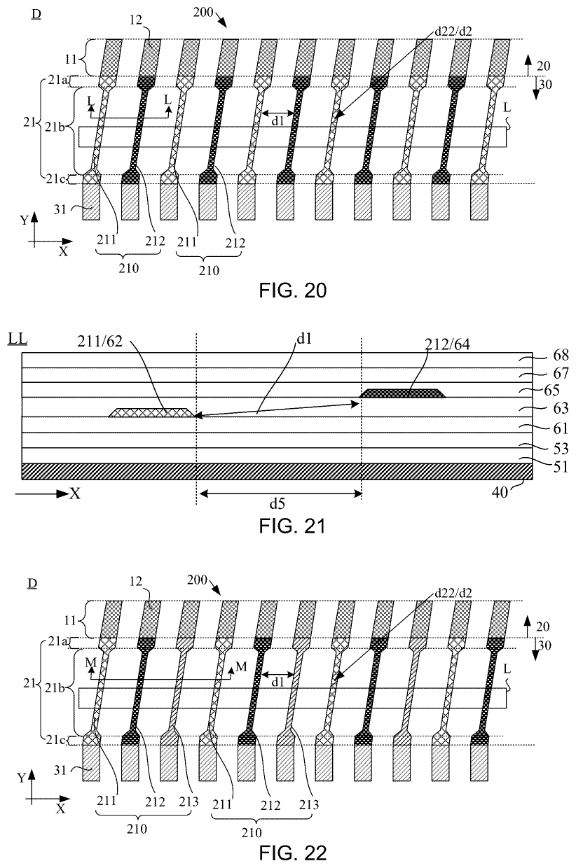

In some examples, as shown in FIGS. 12, 20, and 21, FIG. 21 is a sectional view of the transfer line 21 (the second transfer segment 21b) of the display motherboard 200 shown in FIG. 20 taken along the section line LL. The plurality of conductive layers include: at least two source-drain metal layers. The first-type transfer lines 211 are located in any one of the at least two source-drain metal layers, and the second-type transfer lines 212 are located in a source-drain metal layer other than the source-drain metal layer where the first-type transfer lines 211 are located.

For example, the plurality of conductive layers include three source-drain metal layers, and the three source-drain metal layers are respectively the first source-drain metal layer 62, the second source-drain metal layer 64 and the third source-drain metal layer 66. The first-type transfer lines 211 are located in the first source-drain metal layer 62, and the second-type transfer lines 212 are located in the second source-drain metal layer 64.

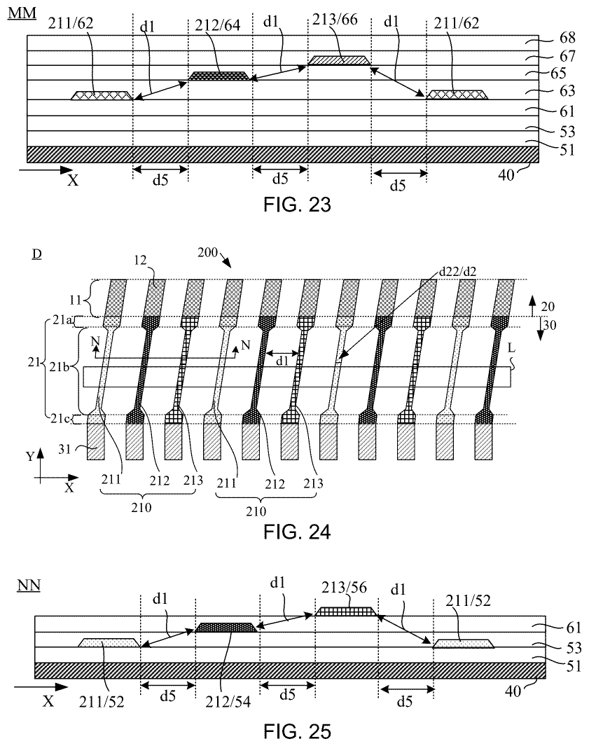

In some embodiments, as shown in FIGS. 22 and 23, FIG. 23 is a sectional view of the transfer line 21 (the second transfer segment 21b) of the display motherboard 200 shown in FIG. 22 taken along the section line MM. The plurality of transfer lines 21 further include a plurality of third-type transfer lines 213. The plurality of third-type transfer lines 213, the plurality of first-type transfer lines 211, and the plurality of second-type transfer lines 212 are located in different conductive layers. The transfer line group 210 further includes a third-type transfer line 213 among the plurality of third-type transfer lines 213.

For example, the first-type transfer lines 211 are located in the first source-drain metal layer 62, the second-type transfer lines 212 are located in the second source-drain metal layer 64, and the third-type transfer lines 213 are located in the third source-drain metal layer 66. For example, one first-type transfer line 211, one second-type transfer line 212, and one third-type transfer line 213 that are arranged in sequence in the first direction X constitute one transfer line group 210. That is, in a single transfer line group 210, the third-type transfer line 213 is located on a side of the second-type transfer line 212 away from the first-type transfer line 211. The plurality of transfer line groups 210 are evenly arranged in the first direction X.

In some examples, as shown in FIGS. 24 and 25, FIG. 25 is a sectional view of the transfer line 21 (the second transfer segment 21b) of the display motherboard 200 shown in FIG. 24 taken along the section line NN. The plurality of conductive layers include three gate metal layers. For example, the three gate metal layers are respectively the first gate metal layer 52, the second gate metal layer 54 and the third gate metal layer 56. The first-type transfer lines 211 are located in the first gate metal layer 52, the second-type transfer lines 212 are located in the second gate metal layer 54, and the third-type transfer lines 213 are located in the third gate metal layer 56.

As shown in FIG. 15, the transfer lines 21 are located in the first gate metal layer 52, and the distance d1 between adjacent transfer lines 21 is a distance d5 between two adjacent transfer lines 21 in the first direction X, that is, d1=d5. As shown in FIGS. 15, 17, 19, 21, 23 and 25, compared with a case where two adjacent transfer lines 21 are located in the same conductive layer, in a case where two adjacent transfer lines 21 are located in different conductive layers, the distance d1 between the two adjacent transfer lines 21 is greater than the distance d5 between the two adjacent transfer lines 21 in the first direction X, that is, d1>d5. That is to say, by arranging that every two adjacent transfer lines 21 are located in different conductive layers, the distance d1 between the two adjacent transfer lines 21 may be increased, thereby reducing the risk of the short circuit between the transfer lines 21 caused by cutting the transfer lines 21.

As shown in FIGS. 1 and 6, the embodiments of the present disclosure further provide a display panel 100, and the display panel 100 includes: a display region 10, a frame region 20 located on at least one side of the display region 10, and a cutting sub-region 102 located on a side of the frame region 20 away from the display region 10. The frame region 20 is provided with a plurality of bonding terminals 12 arranged in a first direction X. The cutting sub-region 102 is provided with a plurality of transfer sub-lines 21q arranged in the first direction X. An end of the transfer sub-line 21q is correspondingly connected to a bonding terminal 12, and another end of the transfer sub-line 21q extends away from the display region 10. In a second direction Y, a width d2 of at least one transfer sub-line 21q varies, and a maximum width of the transfer sub-line 21q is less than or equal to a width d3 of the bonding terminal 12. The second direction Y and the first direction X intersect. The width d2 of the transfer sub-line 21q is a dimension of the transfer sub-line 21q in the first direction X, and the width d3 of the bonding terminal 12 is a dimension of the bonding terminal 12 in the first direction X.

It can be understood that the cutting sub-region 102 is a portion 30B of the cutting region 30 located on a side of a cutting path L close to the frame region 20, and the transfer sub-line 21 q is a portion of the transfer line 21 located on a side of the cutting path L close to the display region 10.

That is, as shown in FIGS. 1, 6 and 16, a portion of the display motherboard 200 on a side of the cutting path L away from the display region 10, i.e., a portion of the cutting region 30 located on the side of the cutting path L away from the display region 10, is removed by cutting along the cutting path L of the cutting region 30 using a laser cutting manner. The display region 10 of the display motherboard 200, the frame region 20, and a portion 30B (i.e., the cutting sub-region 102) of the cutting region 30 located on a side of the cutting path L close to the display region 10 form a display panel 100.

In the second direction Y, the width d2 of at least one transfer sub-line 21q varies, and the maximum width of the transfer sub-line 21q is less than or equal to the width d3 of the bonding terminal 12. That is, a width d2 of a portion of the transfer sub-line 21q in the second direction Y is decreased, thereby increasing a distance d1 between adjacent transfer sub-lines 21q at a position where the width d2 is decreased. Therefore, the risk of a short circuit between the transfer sub-lines 21q may be reduced.

In some examples, as shown in FIG. 6, the transfer sub-line 21q includes a first transfer segment 21 a and a second transfer sub-segment 21bq; an end of the first transfer segment 21a is connected to the bonding terminal 12, another end of the first transfer segment 21 a is connected to an end of the second transfer sub-segment 21bq, and another end of the second transfer sub-segment 21bq extends away from the display region 10. A width d22 of at least a portion of the second transfer sub-segment 21bq is less than a width d21 of the first transfer segment 21a.

That is, in the second direction Y, the width d2 of the transfer sub-line 21q is decreased at the second transfer sub-segment 21bq, thereby reducing the risk of the short circuit between the second transfer sub-segments 21bq.

For example, as shown in FIGS. 13A and 13B, FIG. 13A is a sectional view of the first transfer segment 21a shown in FIG. 6 taken along the section line EE, and FIG. 13B is another sectional view of the first transfer segment 21a shown in FIG. 6 taken along the section line EE. The first transfer segment 21a includes: a portion of a first gate metal layer 52, a portion of a first source-drain metal layer 62 and a portion of a second source-drain metal layer 64 that are arranged in sequence. A portion of a first insulating layer 61 is arranged between two adjacent first transfer segments 21a, and the portion of the first insulating layer 61 covers edges of the two adjacent first transfer segments 21a.

It can be understood that the film layer arrangement of the second transfer sub-segment 21bq is the same as the film layer arrangement of the second transfer segment 21b. As shown in FIG. 15, the second transfer segment 21b includes: a portion of a first gate metal layer 52; and a first insulating layer 61 is arranged on the first gate metal layer 52, and the first insulating layer 61 covers the second transfer segment 21b. Therefore, the second transfer sub-segment 21bq includes: a portion of the first gate metal layer 52, the first insulating layer 61 is arranged on the first gate metal layer 52, and the first insulating layer 61 covers the second transfer sub-segment 21bq.

As shown in FIG. 13A, the first transfer segment 21a further includes a portion of a third source-drain metal layer 66; and the third source-drain metal layer 66 and a second insulating layer 69 are arranged on a side of the second source-drain metal layer 64 away from the first source-drain metal layer 62. A portion of the second insulating layer 69 is located between two adjacent first transfer segments 21a, and the second insulating layer 69 exposes the third source-drain metal layer 66.

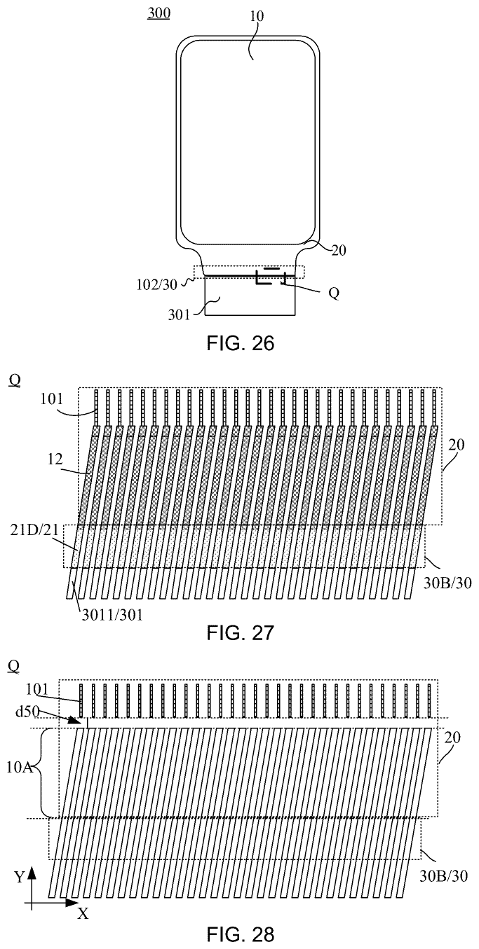

As shown in FIGS. 26 and 27, the embodiments of the present disclosure further provide a display module 300, and the display module 300 includes the display panel 100 described in any of the above embodiments, and a flexible printed circuit board 301. The flexible printed circuit board 301 includes a plurality of leads 3011, and the plurality of leads 3011 are correspondingly connected to a plurality of bonding terminals 12 located in the frame region 20 of the display panel 100.

As shown in FIGS. 27 and 28, the relative positional relationship between the flexible printed circuit board 301 and the frame region 20 can be seen from FIG. 28. The frame region 20 is provided with a plurality of signal lines 101, the plurality of signal lines 101 are correspondingly connected to the plurality of bonding terminals 12, and the plurality of signal lines 101 are used to be connected to circuits of the display region 10 and the frame region 20. A portion 30B of the cutting region 30 retains portions 21D of the transfer lines 21 after cutting. The portions 21D of the transfer lines 21 are not directly connected to the leads 3011 of the flexible printed circuit board 301, and the leads 3011 of the flexible printed circuit board 301 are directly connected to the bonding terminals 12. That is, the flexible printed circuit board 301 and the frame region 20 have an overlapping region 10A. For example, there is a certain distance d50 in the second direction Y between the overlapping region 10A and the plurality of signal lines 101. In the overlapping region 10A, the leads 3011 of the flexible printed circuit board 301 are correspondingly connected to the bonding terminals 12.

The beneficial effects of the display module 300 are the same as the beneficial effects of the display panel 100 provided in any of the above embodiments of the present disclosure, and details are not repeated here.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

1. A display motherboard, comprising:
a display region;
a frame region located on at least one side of the display region and being provided with a plurality of bonding terminals arranged in a first direction; and
a cutting region located on a side of the frame region away from the display region and being provided with a plurality of transfer lines arranged in the first direction, wherein an end of a transfer line of the plurality of transfer lines is correspondingly connected to a bonding terminal of the plurality of bonding terminals, and another end of the transfer line of the plurality of transfer lines extends in a direction away from the display region;
wherein in a second direction, a width of at least one transfer line varies; a maximum width of the transfer line is less than or equal to a width of the bonding terminal; the second direction and the first direction intersect; the width of the transfer line is a dimension of the transfer line in the first direction; and the width of the bonding terminal is a dimension of the bonding terminal in the first direction.

2. The display motherboard according to claim 1, wherein the transfer line includes a first transfer segment, a second transfer segment, and a third transfer segment that are connected in sequence; the first transfer segment is connected to the bonding terminal; the third transfer segment extends in the direction away from the display region;
a width of at least a portion of the second transfer segment is less than a width of the first transfer segment, and is less than a width of the third transfer segment.

3. The display motherboard according to claim 2, wherein in the second direction, a width of the second transfer segment is equal.

4. The display motherboard according to claim 2, wherein in the second direction, the second transfer segment includes a first segment and a second segment; a first end of the first segment is connected to the first transfer segment, a second end of the first segment is connected to a second end of the second segment, and a first end of the second segment is connected to the third transfer segment;
a width of the first segment is decreased in a direction from the first end of the first segment to the second end of the first segment; and
a width of the second segment is decreased in a direction from the first end of the second segment to the second end of the second segment.

5. The display motherboard according to claim 4, wherein
a rate of change at which the width of the first segment is decreased in the direction from the first end of the first segment to the second end of the first segment remains constant; and
a rate of change at which the width of the second segment is decreased in the direction from the first end of the second segment to the second end of the second segment remains constant.

6. The display motherboard according to claim 4, wherein
in the direction from the first end of the first segment to the second end of the first segment, the first segment includes a plurality of first sub-segments connected in sequence, and a width of a first sub-segment relatively far away from the first transfer segment is less than a width of a first sub-segment relatively close to the first transfer segment;
in the direction from the first end of the second segment to the second end of the second segment, the second segment includes a plurality of second sub-segments connected in sequence, and a width of a second sub-segment relatively far away from the third transfer segment is less than a width of a second sub-segment relatively close to the third transfer segment.

7. The display motherboard according to claim 2, wherein in the second direction, the second transfer segment of the transfer line includes: a plurality of third sub-segments and a plurality of fourth sub-segments that are alternately arranged and connected;
a width of each third sub-segment of the plurality of third sub-segments is greater than a width of any fourth sub-segment of the plurality of fourth sub-segments.

8. The display motherboard according to claim 7, wherein the width of each third sub-segment is equal, and a width of each fourth sub-segment is equal.

9. The display motherboard according to claim 7, wherein the width of each third sub-segment is equal;
in the second direction, the second transfer segment has a middle position; in a direction from the first transfer segment of the transfer line to the middle position, a width of a fourth sub-segment relatively far away from the first transfer segment is less than a width of a fourth sub-segment relatively close to the first transfer segment;
in a direction from the third transfer segment of the transfer line to the middle position, a width of a fourth sub-segment relatively far away from the third transfer segment is less than a width of a fourth sub-segment relatively close to the third transfer segment.

10. The display motherboard according to claim 2, wherein the display motherboard comprises: a plurality of conductive layers and a plurality of insulating layers that are alternately arranged; wherein
the cutting region includes: a first region, a second region and a third region; the first transfer segment of the transfer line is located in the first region, the second transfer segment of the transfer line is located in the second region, and the third transfer segment of the transfer line is located in the third region;
an insulating layer in the first region includes an organic film layer and/or an inorganic film layer; an insulating layer in the second region includes an inorganic film layer; and
an insulating layer in the third region includes an organic film layer and/or an inorganic film layer.

11. The display motherboard according to claim 1, wherein the display motherboard comprises: a plurality of conductive layers and an inorganic insulating layer located between every two adjacent conductive layers among the plurality of conductive layers;
wherein at least a pair of two adjacent transfer lines are located in different conductive layers.

12. The display motherboard according to claim 11, wherein the plurality of transfer lines include: a plurality of first-type transfer lines and a plurality of second-type transfer lines; the plurality of first-type transfer lines and the plurality of second-type transfer lines are located in different conductive layers;
in the first direction, the plurality of transfer lines are divided into a plurality of transfer line groups arranged side by side; each transfer line group of the plurality of transfer line groups includes: a first-type transfer line among the plurality of first-type transfer lines and a second-type transfer line among the plurality of second-type transfer lines.

13. The display motherboard according to claim 12, wherein the plurality of conductive layers include at least one gate metal layer and at least one source-drain metal layer; the first-type transfer lines are located in any one of the at least one gate metal layer, and the second-type transfer lines are located in any one of the at least one source-drain metal layer; or
the plurality of conductive layers include at least two gate metal layers; the first-type transfer lines are located in any one of the at least two gate metal layers, and the second-type transfer lines are located in a gate metal layer other than a gate metal layer where the first-type transfer lines are located; or
the plurality of conductive layers include at least two source-drain metal layers; the first-type transfer lines are located in any one of the at least two source-drain metal layers, and the second-type transfer lines are located in a source-drain metal layer other than a source-drain metal layer where the first-type transfer lines are located.

14. The display motherboard according to claim 12, wherein the plurality of transfer lines further include a plurality of third-type transfer lines; the plurality of third-type transfer lines, the plurality of first-type transfer lines, and the plurality of second-type transfer lines are located in different conductive layers;
the transfer line group further includes: a third-type transfer line among the plurality of third-type transfer lines.

15. The display motherboard according to claim 14, wherein in a single transfer line group, a third-type transfer line is located on a side of a second-type transfer line away from a first-type transfer line.

16. The display motherboard according to claim 2, wherein the first transfer segment includes: a portion of a first gate metal layer, a portion of a first source-drain metal layer, and a portion of a second source-drain metal layer that are arranged in sequence; a portion of a first insulating layer is arranged between two adjacent first transfer segments, and the portion of the first insulating layer covers edges of the two adjacent first transfer segments;
the second transfer segment includes: a portion of the first gate metal layer and a the first insulating layer is arranged on the first gate metal layer, and the first insulating layer covers the second transfer segment.

17. The display motherboard according to claim 16, wherein the first transfer segment further includes a portion of a third source-drain metal layer; the third source-drain metal layer and a second insulating layer are arranged on a side of the second source-drain metal layer away from the first source-drain metal layer: and a portion of the second insulating layer is located between two adjacent first transfer segments, and the second insulating layer exposes the third source-drain metal layer.

18. (canceled)

19. A display panel, comprising:
a display region;
a frame region located on at least one side of the display region and being provided with a plurality of bonding terminals arranged in a first direction; and
a cutting sub-region located on a side of the frame region away from the display region and being provided with a plurality of transfer sub-lines arranged in a first direction, wherein an end of a transfer sub-line is correspondingly connected to a bonding terminal, and another end of the transfer sub-line extends in a direction away from the display region;
wherein in a second direction, a width of at least one transfer sub-line varies; a maximum width of the transfer sub-line is less than or equal to a width of the bonding terminal;
the second direction and the first direction intersect; the width of the transfer sub-line is a dimension of the transfer sub-line in the first direction; and the width of the bonding terminal is a dimension of the bonding terminal in the first direction.

20. The display panel according to claim 19, wherein the transfer sub-line includes a first transfer segment and a second transfer sub-segment; an end of the first transfer segment is connected to the bonding terminal, another end of the first transfer segment is connected to an end of the second transfer sub-segment, and another end of the second transfer sub-segment extends in the direction away from the display region;
a width of at least a portion of the second transfer sub-segment is less than a width of the first transfer segment.

21. A display module, comprising:
the display panel according to claim 19; and
a flexible printed circuit board, wherein the flexible printed circuit board includes a plurality of leads, and the plurality of leads are correspondingly connected to the plurality of bonding terminals located in the frame region of the display panel.
